(19) United States
(12) Patent Application Publication
(10) Pub. No.: US 2026/0144094 A1
(43) Pub. Date: May 21, 2026

(54) SEMICONDUCTOR DEVICE INCLUDING LOGIC DIE AND PROCESSOR DIE

(71) Applicant: SAMSUNG ELECTRONICS CO., LTD., Suwon-si (KR)

(72) Inventors: Hun Seong CHOI, Suwon-si (KR); Tae-Hwang KONG, Suwon-si (KR); Eunhwan KIM, Suwon-si (KR); Seok Ju YUN, Suwon-si (KR); Seungchul JUNG, Suwon-si (KR); Sungeun JO, Suwon-si (KR)

(73) Assignee: SAMSUNG ELECTRONICS CO., LTD., Suwon-si (KR)

(21) Appl. No.: 19/086,932

(22) Filed: Mar. 21, 2025

(30) Foreign Application Priority Data
Nov. 21, 2024 (KR) 10-2024-0167426

(51) Int. Cl. H01L 23/538; H01L 23/00; H01L 23/13; H01L 23/48; H01L 25/00; H01L 25/16

(52) U.S. Cl. CPC H10W 70/614; H10W 20/20; H10W 70/611; H10W 70/68; H10W 90/00; H10W 90/401; H10W 90/722; H10W 90/792

(57) ABSTRACT

A semiconductor device may include: a package substrate; a redistribution substrate on the package substrate in a first direction; a logic die embedded in the redistribution substrate so that at least a portion of the logic die is exposed from a surface of the redistribution substrate, the surface facing in the first direction, and the logic die including an active circuit and a first connection area; a memory stack including a plurality of memory dies stacked on the logic die in the first direction; and a processor die on the redistribution substrate in the first direction, the processor die including a second connection area overlapping with the first connection area in the first direction, wherein wiring of the logic die and wiring of the processor die are electrically connected through a first bonding portion on the first connection area and the second connection area.

### CROSS-REFERENCE TO RELATED APPLICATION

This application claims the benefit of Korean Patent Application No. 10-2024-0167426, filed on Nov. 21, 2024, in the Korean Intellectual Property Office, the entire disclosure of which is incorporated herein by reference for all purposes.

### BACKGROUND

### 1. Field

Various embodiments of the disclosure relate to a semiconductor device including a logic die and a processor die.

### 2. Description of Background Art

Modern electronic devices require high performance and energy efficiency, and semiconductor integrated circuit (IC) technology is continuously developing to meet demands. In particular, with the rapid development of high-performance computing devices, artificial intelligence (AI) processors, graphics processing units (GPUs), data sensors, and mobile devices, higher processing rates and the capability of processing more data are required.

To satisfy such demands, multi-die or system-on-chip (SoC) technology is widely used in semiconductor industries. These technologies enable multiple processors, memories, and various functional blocks to be integrated and operated in a single package, contributing to performance and special efficiency improvement.

However, signal integrity and power consumption remain important challenges in implementing efficient connection and communication between dies. In particular, in high-performance systems, optimizing the data transmission speed between multiple processors and a memory while maintaining reliability is important. To this end, new packaging techniques and power management solutions are required.

Further, miniaturization and high-density integration of semiconductor devices are increasing precision and complexity in the manufacturing process, which in turn increases manufacturing costs. Therefore, innovative design and packaging techniques that are more cost-effective while maintaining high performance are needed.

The above information may be presented as background art to help with the understanding of the disclosure. No admission is made as to whether any of the above is applicable as prior art with respect to the present application.

### SUMMARY

According to an aspect of the disclosure, a semiconductor device may be provided and include: a package substrate; a redistribution substrate on the package substrate in a first direction; a logic die embedded in the redistribution substrate so that at least a portion of the logic die is exposed from a surface of the redistribution substrate, the surface facing in the first direction, and the logic die including an active circuit and a first connection area; a memory stack including a plurality of memory dies stacked on the logic die in the first direction; and a processor die on the redistribution substrate in the first direction, the processor die including a second connection area overlapping with the first connection area in the first direction, wherein wiring of the logic die and wiring of the processor die are electrically connected through a first bonding portion on the first connection area and the second connection area so that wiring of the logic die and wiring of the processor die are at least partially aligned in the first direction.

According to an aspect of the disclosure, the first bonding portion may include a micro bump or hybrid copper bonding structure.

According to an aspect of the disclosure, the memory stack may be configured to transmit and receive data to and from the processor die via a pathway including the logic die and not including the redistribution substrate.

According to an aspect of the disclosure, the logic die may include: a signal path for transmitting and receiving data between the memory stack and the processor die; and a signal driver configured to adjust a signal transmitted along the signal path.

According to an aspect of the disclosure, the signal path may include: a first through-silicon via in the first connection area, the first through-silicon via electrically connected to the processor die through the first bonding portion; a second through-silicon via electrically connected to the memory stack through a second bonding portion; and connection wiring electrically connecting the first through-silicon via and the second through-silicon via.

According to an aspect of the disclosure, the signal path may include connection wiring in an upper portion of the logic die, and wherein one side of the connection wiring may be electrically connected to the processor die through the first bonding portion, and another side of the connection wiring may be electrically connected to the memory stack through a second bonding portion.

According to an aspect of the disclosure, the logic die may include at least one from among an integrated voltage regulator (IVR), a memory controller (MC), a switch circuit, a network-on-chip (NoC), a static random-access memory (SRAM), a digital signal processor (DSP), and a neural processing unit (NPU).

According to an aspect of the disclosure, the logic die and the processor die may be configured to transmit and receive data at a first bandwidth through the signal path of the logic die, and transmit and receive data at a second bandwidth through wiring of the redistribution substrate, and wherein the first bandwidth may be higher than the second bandwidth.

According to an aspect of the disclosure, the redistribution substrate may include an organic substrate, and wherein the logic die may include a silicon substrate, a gallium nitride (GaN) substrate, or a glass substrate.

According to an aspect of the disclosure, the semiconductor device may further include an additional processor die on the redistribution substrate in the first direction, wherein the processor die and the additional processor die may overlap with the logic die in the first direction, and may be electrically connected to the logic die.

According to an aspect of the disclosure, the semiconductor device may further include a unit structure including the logic die, the memory stack, the processor die, and the additional processor die, wherein the semiconductor device may include a plurality of the unit structure on the redistribution substrate.

According to an aspect of the disclosure, the processor die of a first unit structure, from among the plurality of the unit structure, and the processor die of a second unit structure, from among the plurality of the unit structure, may be electrically connected through wiring of the redistribution substrate.

According to an aspect of the disclosure, a semiconductor device may be provided and include: a redistribution substrate; a memory stack including: a base die embedded in the redistribution substrate so that at least a portion of the base die is exposed from a surface of the redistribution substrate, the surface facing in a first direction; and a memory die on the base die in the first direction; and a processor die on the redistribution substrate in the first direction, the processor die including an area overlapping with the base die in the first direction, wherein the base die and the processor die are connected to each other through a bonding portion on the area, and wherein the base die includes a signal amplifying element or a buffering element.

According to an aspect of the disclosure, the memory die may be configured to transmit and receive data to and from the processor die via a pathway including the base die and not including the redistribution substrate.

According to an aspect of the disclosure, the base die may include a signal path for transmitting and receiving data between the memory die and the processor die.

According to an aspect of the disclosure, the signal path may include: a first through-silicon via electrically connected to the processor die; a second through-silicon via electrically connected to the memory die; and connection wiring electrically connecting the first through-silicon via and the second through-silicon via.

According to an aspect of the disclosure, the base die and the processor die may be bonded through a micro bump or hybrid copper bonding structure on the area.

According to an aspect of the disclosure, a method of manufacturing a semiconductor device may be provided and include: embedding a logic die in a redistribution substrate such that at least a portion of the logic die is exposed from a surface of the redistribution substrate, the surface facing in a first direction, and the logic die including an active circuit; stacking a plurality of memory dies on the logic die in the first direction; and stacking a processor die on the redistribution substrate in the first direction such that an area of the processor die overlaps with the logic die in the first direction, wherein the stacking the processor die includes connecting the logic die and the processor die through a bonding portion on the area.

According to an aspect of the disclosure, the bonding portion may include a micro bump or a hybrid copper bonding structure.

According to an aspect of the disclosure, the embedding the logic die in the redistribution substrate may include: forming a cavity in the surface of the redistribution substrate; placing the logic die in the cavity; and laminating around the logic die.

Additional aspects of embodiments of the disclosure will be set forth in part in the description which follows and, in part, will be apparent from the description, or may be learned by practice of the disclosure.

### BRIEF DESCRIPTION OF DRAWINGS

These and/or other aspects, features, and advantages of the disclosure will become apparent and more readily appreciated from the following description of example embodiments, taken in conjunction with the accompanying drawings of which:

FIG. 1 is a schematic perspective view of a semiconductor device according to an embodiment;

FIG. 2 is a schematic cross-sectional view of a semiconductor device according to an embodiment;

FIG. 3 is a schematic plan view of a semiconductor device according to an embodiment;

FIG. 4 is a schematic cross-sectional view of a semiconductor device according to an embodiment;

FIG. 5 is a schematic plan view of a semiconductor device according to an embodiment;

FIG. 6 is a schematic plan view of a semiconductor device according to an embodiment;

FIG. 7 is a schematic plan view of a semiconductor device according to an embodiment;

FIG. 8 is a partial cross-sectional view of a semiconductor device according to an embodiment, the partial cross-sectional view taken along a line A-A of FIG. 7;

FIG. 9 is a partial cross-sectional view of a semiconductor device according to an embodiment, the partial cross-sectional view taken along the line A-A of FIG. 7;

FIG. 10 is a schematic plan view of a semiconductor device according to an embodiment;

FIG. 11 is a schematic plan view of a semiconductor device according to an embodiment;

FIG. 12 is a schematic plan view of a semiconductor device according to an embodiment;

FIG. 13 is a schematic perspective view of a semiconductor device according to an embodiment;

FIG. 14 is a schematic partial cross-sectional view of a semiconductor device according to an embodiment;

FIG. 15 is a schematic partial cross-sectional view of a semiconductor device according to an embodiment; and

FIG. 16 is a flowchart illustrating a method of manufacturing a semiconductor device according to an embodiment.

### DETAILED DESCRIPTION

Hereinafter, non-limiting example embodiments of the disclosure will be described in detail with reference to the accompanying drawings. However, various alterations and modifications may be made to the example embodiments. The embodiments of the disclosure are not meant to be limited by the descriptions of the present disclosure. The embodiments of the disclosure should be understood to include all changes, equivalents, and replacements within the spirit and scope of the disclosure.

The terminology used herein is for the purpose of describing particular example embodiments only and is not intended to be limiting. The singular forms “a,” “an,” and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms, including technical and scientific terms, used herein have the same meaning as commonly understood by one of ordinary skill in the art to which this disclosure pertains. Terms, such as those defined in commonly used dictionaries, are to be interpreted as having a meaning that is consistent with their meaning in the context of the relevant art, and are not to be interpreted in an idealized or overly formal sense unless expressly so defined herein.

When describing the example embodiments with reference to the accompanying drawings, like reference numerals refer to like components and a repeated description related thereto may be omitted. In the description of example embodiments, detailed description of well-known related structures or functions may be omitted when it is deemed that such description will cause ambiguous interpretation of the present disclosure.

Also, in the description of the components, terms such as “first,” “second,” “A,” “B,” “(a),” “(b),” or the like may be used herein when describing components of the present disclosure. These terms are used only for the purpose of distinguishing one component from another component, and the nature, the sequences, or the orders of the components are not limited by the terms. When one constituent element is described as being “connected,” “coupled,” or “attached” to another constituent element, it should be understood that one constituent element can be connected or attached directly to another constituent element, and an intervening constituent element can also be “connected,” “coupled,” or “attached” to the constituent elements.

The same name may be used to describe an element included in example embodiments and an element having a common function. Unless otherwise mentioned, the descriptions of examples of the present disclosure may be applicable to other examples (e.g., following examples) of the present disclosure, and thus, duplicated descriptions may be omitted for conciseness.

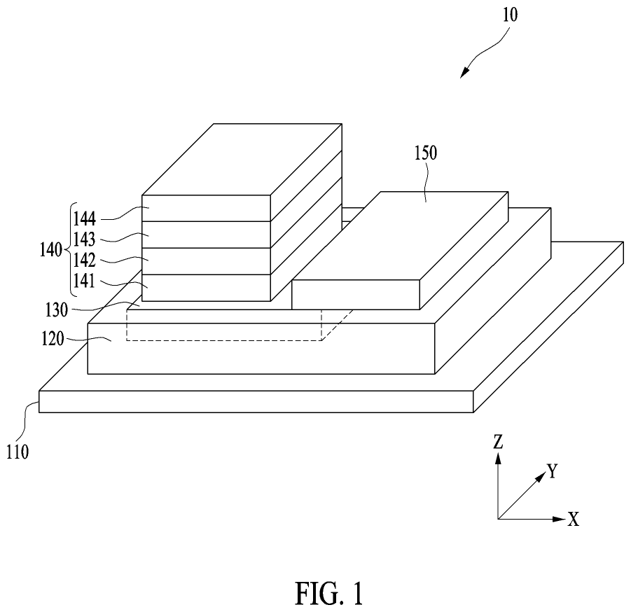

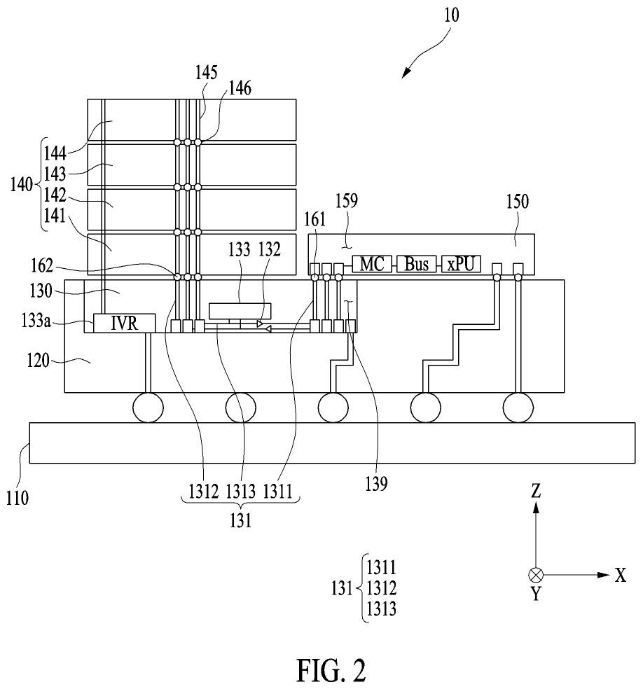

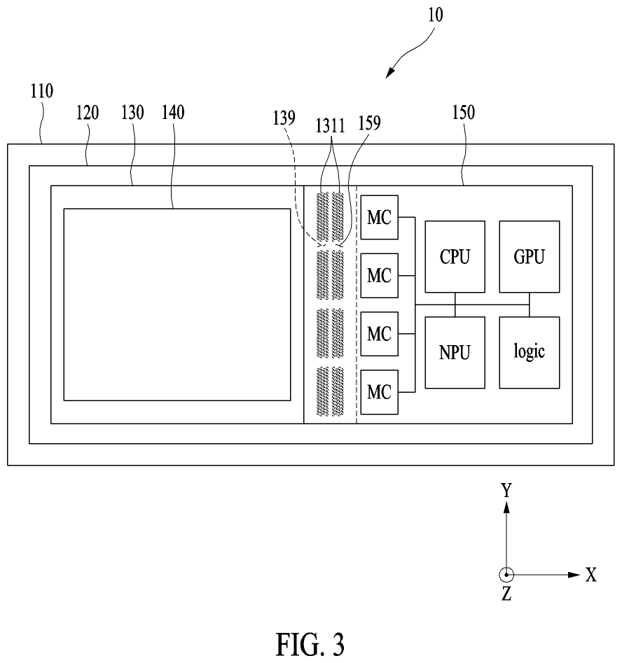

FIG. 1 is a schematic perspective view of a semiconductor device according to an embodiment. FIG. 2 is a schematic cross-sectional view of the semiconductor device according to an embodiment. FIG. 3 is a schematic plan view of the semiconductor device according to an embodiment. In describing the semiconductor device according to an embodiment with reference to FIGS. 1 to 3, the upward direction may be the +Z direction, and the downward direction may be the −Z direction, unless otherwise described.

Referring to FIGS. 1 to 3, according to an embodiment, a semiconductor device 10 may include a semiconductor device including a high bandwidth memory (HBM). For example, the semiconductor device 10 may also be referred to as a semiconductor package or a semiconductor structure.

In an embodiment, the semiconductor device 10 may include a package substrate 110, a redistribution substrate 120, a logic die 130, a memory stack 140, and a processor die 150.

In an embodiment, the package substrate 110 may be a substrate on which each component (e.g., the redistribution substrate 120, the logic die 130, the memory stack 140, and/or the processor die 150) of the semiconductor device 10 is disposed. A pad and/or a solder ball for connection with the outside may be formed on the package substrate 110.

In an embodiment, the redistribution substrate 120 may be stacked on the package substrate 110. The logic die 130, the memory stack 140, and/or the processor die 150 may be disposed on the redistribution substrate 120. The redistribution substrate 120 may be a substrate for electrically connecting a component (e.g., the logic die 130, the memory stack 140, and/or the processor die 150) disposed in and/or on the upper portion of the redistribution substrate 120 and a component (e.g., the package substrate 110) disposed in and/or on the lower portion of the redistribution substrate 120 to each other. For example, the redistribution substrate 120 may be configured as an interposer having a redistribution function. To this end, wiring of various paths may be formed in and/or on the redistribution substrate 120. Meanwhile, the redistribution substrate 120 may include wiring paths for electrically connecting the components disposed in and/or on the upper portion of the redistribution substrate 120 to each other. For example, the logic die 130 and the processor die 150 disposed on the redistribution substrate 120 may be electrically connected to each other through the wiring of the redistribution substrate 120. The redistribution substrate 120 may be formed of, for example, an organic substrate. In this case, the redistribution substrate 120 may be easily manufactured as a large area. However, this is merely an example, and the type of the redistribution substrate 120 is not limited thereto. For example, the redistribution substrate 120 may be formed of a silicon substrate, a gallium nitride (GaN) substrate, or a glass substrate.

In an embodiment, the logic die 130 may be embedded in the redistribution substrate 120 so that at least a portion of the logic die 130 may be exposed from the top surface of the redistribution substrate 120. For example, as shown in FIG. 1, the logic die 130 may be embedded in the upper portion of the redistribution substrate 120 so that the top surface of the logic die 130 may be exposed from the top surface of the redistribution substrate 120. For example, the top surface of the logic die 130 and the top surface of the redistribution substrate 120 may be positioned substantially on a same plane. The logic die 130 may be formed of, for example, a silicon substrate. However, this is merely an example, and the type of the logic die 130 is not limited thereto. For example, the logic die 130 may be formed of an organic substrate, a GaN substrate, or a glass substrate.

In an embodiment, the memory stack 140 may be stacked on the logic die 130. The memory stack 140 may include a plurality of memory dies 141, 142, 143, and 144. The plurality of memory dies 141, 142, 143, and 144 may be vertically stacked on each other and electrically connected to each other. For example, the plurality of memory dies 141, 142, 143, and 144 may be electrically connected to each other through at least one through via 145 and at least one micro bump 146. The through via 145 may be, for example, a through-silicon via (TSV). However, this is merely an example, and the method of electrically connecting the plurality of memory dies 141, 142, 143, and 144 to each other is not limited thereto. The lowest memory die (e.g., the memory die 141) may be electrically connected to the logic die 130 through a second bonding portion 162. For example, the second bonding portion 162 may include a bonding pad and a micro bump, or may include a hybrid copper bonding structure for directly connecting a die and a die. However, this is merely an example, and the type of the second bonding portion 162 is not limited thereto. For example, the second bonding portion 162 may include a copper (Cu) pillar bump or a solder bump. Meanwhile, although four memory dies 141, 142, 143, and 144 are shown in the drawings for ease of description, the number of memory dies is not limited thereto.

In an embodiment, the processor die 150 may be stacked on the redistribution substrate 120. For example, the processor die 150 may be positioned at a position close to the memory stack 140. The processor die 150 may be a component configured to process data received from the memory stack 140. The processor die 150 may include various processor cores configured to process data. For example, the processor die 150 may include a memory controller (MC), a central processing unit (CPU), a graphics processing unit (GPU), a neural processing unit (NPU), and/or a logic circuit. However, this is merely an example, and the circuit included in the processor die 150 is not limited thereto.

In an embodiment, the logic die 130 and the processor die 150 may be positioned to at least partially vertically overlap with each other. The logic die 130 may include a first connection area 139 which may be an area to be electrically connected to the processor die 150. The processor die 150 may include a second connection area 159 positioned to vertically overlap with the first connection area 139. The first connection area 139 may be construed as an area vertically overlapping with the processor die 150, from among areas of the logic die 130, and the second connection area 159 may be construed as an area vertically overlapping with the logic die 130, from among areas of the processor die 150. In other words, the first connection area 139 of the logic die 130 may vertically overlap with the second connection area 159 of the processor die 150.

In an embodiment, the logic die 130 and the processor die 150 may be electrically connected to each other through the first connection area 139 and the second connection area 159. The logic die 130 and the processor die 150 may be directly connected to each other through a first bonding portion 161 on the first connection area 139 and the second connection area 159. For example, the logic die 130 and the processor die 150 may be connected through the first bonding portion 161 on the first connection area 139 and the second connection area 159 so that the wiring (e.g., a first through-silicon via 1311) of the logic die 130 and the wiring (e.g., a contact pad) of the processor die 150 may be at least partially vertically (e.g., in the z direction) aligned. For example, the first bonding portion 161 may include a bonding pad and a micro bump, or may include a hybrid copper bonding structure for directly connecting a die and a die. However, this is merely an example, and the type of the first bonding portion 161 is not limited thereto. For example, the first bonding portion 161 may include a copper (Cu) pillar bump or a solder bump. By the connection structure described above, the logic die 130 and the processor die 150 may be directly and electrically connected to each other through the overlapping areas (e.g., the first connection area 139 and the second connection area 59), not via the redistribution substrate 120.

In an embodiment, the logic die 130 may electrically connect the memory stack 140 and the processor die 150. For example, the logic die 130 may be connected to each of the memory stack 140 and the processor die 150 in a face-to-back manner as shown in FIG. 2. The logic die 130 may provide a connection path for transmitting and receiving data between the memory stack 140 and the processor die 150. For example, the memory stack 140 may transmit and receive data to and from the processor die 150 via the logic die 130, not via the redistribution substrate 120. The logic die 130 may function as an active bridge electrically connecting the memory stack 140 and the processor die 150 while including an active circuit. The logic die 130 may include a signal path 131 and a signal driver 132.

In an embodiment, the signal path 131 may be a path for transmitting and receiving data between the memory stack 140 and the processor die 150. The signal path 131 may be a path for transmitting and receiving data at high bandwidth. For example, the signal path 131 may include a plurality of paths disposed densely to have high density. For example, each path of the signal path 131 may be formed to have a pitch of 50 micrometers or less. For example, the signal path 131 may include the first through-silicon via 1311, a second through-silicon via 1312, and connection wiring 1313. The first through-silicon via 1311 may be electrically connected to the processor die 150 through the first bonding portion 161. The first through-silicon via 1311 may be positioned in the first connection area 139. The second through-silicon via 1312 may be electrically connected to the memory stack 140 through the second bonding portion 162. The second through-silicon via 1312 may be positioned in an area of the logic die 130 vertically overlapping with the memory stack 140. The connection wiring 1313 may electrically connect the first through-silicon via 1311 and the second through-silicon via 1312. For example, the connection wiring 1313 may include horizontal wiring formed in the logic die 130. For example, if the logic die 130 and the processor die 150 are connected in the face-to-back manner as shown in FIG. 2, the connection wiring 1313 may be positioned in the lower portion of the logic die 130. However, this is merely an example, and the specific path of the signal path 131 is not limited thereto.

In an embodiment, the signal driver 132 may be a component configured to adjust a signal transmitted along the signal path 131. The signal driver 132 may be formed in the logic die 130 so as to be electrically connected to the signal path 131 (e.g., the connection wiring 1313). The signal driver 132 may be a component configured to reduce a loss or distortion of the signal transmitted along the signal path 131 and increase the reliability and rate of data transmission. For example, the signal driver 132 may include an active circuit configured to adjust (e.g., buffer and/or amplify) a signal of the data transmitted and received between the memory stack 140 and the processor die 150. For example, the signal driver 132 may include a buffer, and/or an inverter circuit. However, this is merely an example, and the type of the signal driver 132 is not limited thereto, and the signal driver 132 may include various active circuits, and/or transistors.

In an embodiment, the logic die 130 may further include various active circuits 133. Depending on the embodiment, active circuits that can be provided in the processor die 150 may be provided in the logic die 130. For example, the logic die 130 may further include at least one from among an integrated voltage regulator (IVR), a memory controller (MC), a switch circuit, a network-on-chip (NoC), a static random-access memory (SRAM), a digital signal processor (DSP), and a neural processing unit (NPU). For example, as shown in FIG. 2, the logic die 130 may include an IVR 133a. The IVR 133a may be a circuit configured to supply and/or distribute power to the logic die 130, the memory stack 140, and/or the processor die 150. However, this is merely an example, and the active circuit 133 included in the logic die 130 is not limited thereto.

In an embodiment, the memory stack 140 and the processor die 150 may transmit and receive data at high bandwidth through the high-density signal path (e.g., the signal path 131) formed in the logic die 130, via the logic die 130 only, not via the redistribution substrate 120. Here, the logic die 130 and the processor die 150 may be directly and electrically connected to each other through the first connection area 139 and the second connection area 159 that overlap with each other, and thus, a separate physical (PHY) circuit may be omitted. That is, by the structure of the embodiment, even without a separate PHY circuit, high-bandwidth data transmission and reception between the memory stack 140 and the processor die 150 may be implemented through the logic die 130 including the high-density signal path (e.g., the signal path 131) and the signal driver 132. Through the structure that includes an active circuit, such as the signal driver 132, in the logic die 130 and secures connectivity using the overlapping structure of the logic die 130 and the processor die 150, it is possible to ensure overall yield while increasing the die area and reducing manufacturing costs. Since the redistribution substrate 120 may be manufactured in the panel-level packaging form, it is possible to improve manufacturing efficiency and reduce manufacturing costs. Depending on the embodiment, various active circuits 133 may be added to the logic die 130, thereby improving design expandability.

Meanwhile, the memory stack 140 and the processor die 150 may also transmit and receive data via the redistribution substrate 120. For example, the memory stack 140 and the processor die 150 may transmit and receive data via the wiring of the logic die 130 and the wiring of the redistribution substrate 120. For example, the wiring of the redistribution substrate 120 may be formed at a lower density than a density of the signal path 131 of the logic die 130 described above. For example, in transmitting and receiving data at relatively low bandwidth, data may be transmitted and received between the memory stack 140 and the processor die 150 via the wiring of the logic die 130 and the wiring of the redistribution substrate 120.

In an embodiment, the logic die 130 may be configured as a base die (e.g., a buffer die) of a memory device. For example, the memory device may include a base die (e.g., the logic die 130) and at least one memory die (e.g., the memory stack 140). For example, the base die (e.g., the logic die 130) may be embedded in the redistribution substrate 120 so that at least a portion thereof may be exposed from the top surface of the redistribution substrate 120. The base die (e.g., the logic die 130) may include an active circuit. For example, the base die (e.g., the logic die 130) may include a signal amplifying element, and/or a buffering element. The at least one memory die (e.g., the memory stack 140) may be stacked on the base die (e.g., the logic die 130). The at least one memory die (e.g., the memory stack 140) may be provided in plural and vertically stacked. The processor die 150 may be stacked on the redistribution substrate 120. The processor die 150 may include a second connection area 159 vertically overlapping with the base die (e.g., the logic die 130). The base die (e.g., the logic die 130) and the processor die 150 may be connected to each other through a first bonding portion 161 on the overlapping area (e.g., the second connection area 159). The memory die 140 may transmit and receive data to and from the processor die 150 via the base die (e.g., the logic die 130), not via the redistribution substrate 120. The base die (e.g., the logic die 130) may include a signal path 131 for transmitting and receiving data between the memory die (e.g., the memory stack 140) and the processor die 150. The signal path 131 may include a first through-silicon via 1311 electrically connected to the processor die 150, a second through-silicon via 1312 electrically connected to the at least one memory die (e.g., the memory stack 140), and connection wiring 1313 electrically connecting the first through-silicon via 1311 and the second through-silicon via 1312 to each other. The base die (e.g., the logic die 130) and the processor die 150 may be bonded through a micro bump or hybrid copper bonding structure on the overlapping area (e.g., the second connection area 159). By the structure described above, even without a separate PHY circuit, high-bandwidth data transmission and reception between the at least one memory die (e.g., the memory stack 140) and the processor die 150 may be implemented through the base die (e.g., the logic die 130) including an active circuit (e.g., a signal amplifying element, and/or a buffering element).

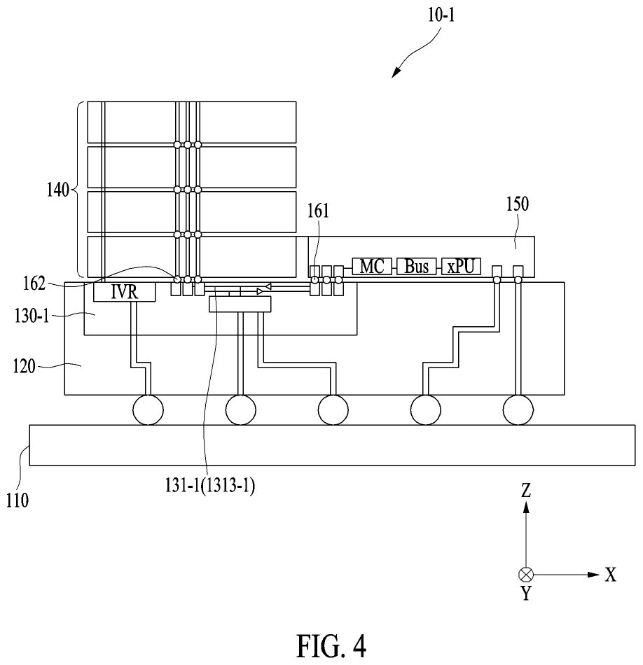

FIG. 4 is a schematic cross-sectional view of a semiconductor device according to an embodiment. In describing a semiconductor device 10-1 of FIG. 4, the description of the semiconductor device 10 provided with reference to FIGS. 1 to 3 may apply thereto, unless otherwise described.

Referring to FIG. 4, in an embodiment, a logic die 130-1 may be connected to each of the memory stack 140 and the processor die 150 in a face-to face manner. A signal path 131-1 of the logic die 130-1 may include connection wiring 1313-1 formed in an upper (e.g., Z-directional) portion of the logic die 130-1. For example, one side (e.g., the +X-directional portion) of the connection wiring 1313-1 may be electrically connected to the processor die 150 through the first bonding portion 161, and the other side (e.g., the −X-directional portion) of the connection wiring 1313-1 may be electrically connected to the memory stack 140 through the second bonding portion 162. Compared to the face-to-back manner described with reference to FIG. 2, the face-to-face manner of FIG. 4 may allow the signal path 131-1 to be shorter, which may be advantageous for high-speed data communication. Meanwhile, the face-to-back manner of FIG. 2 may be advantageous in terms of power supply and heat dissipation.

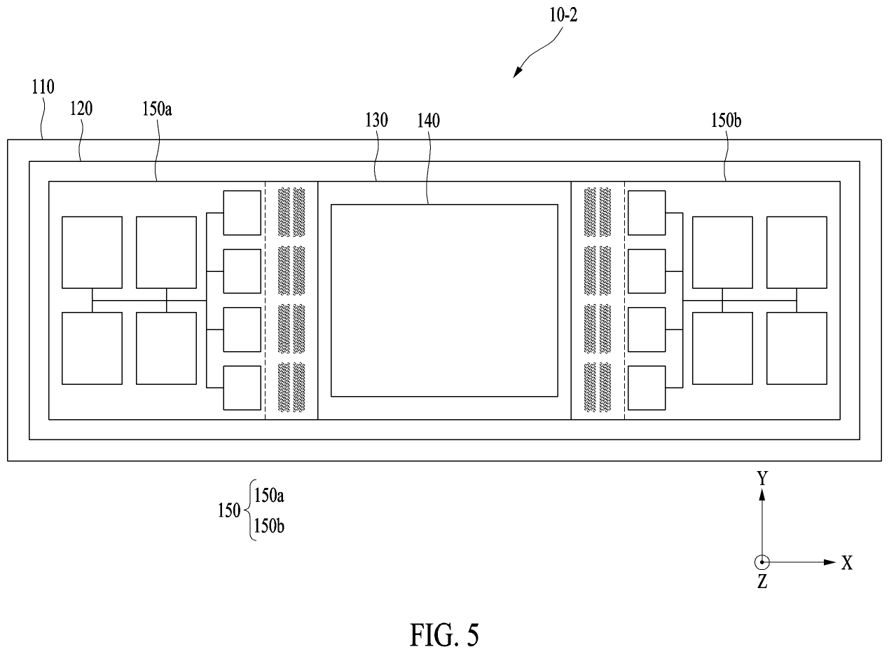

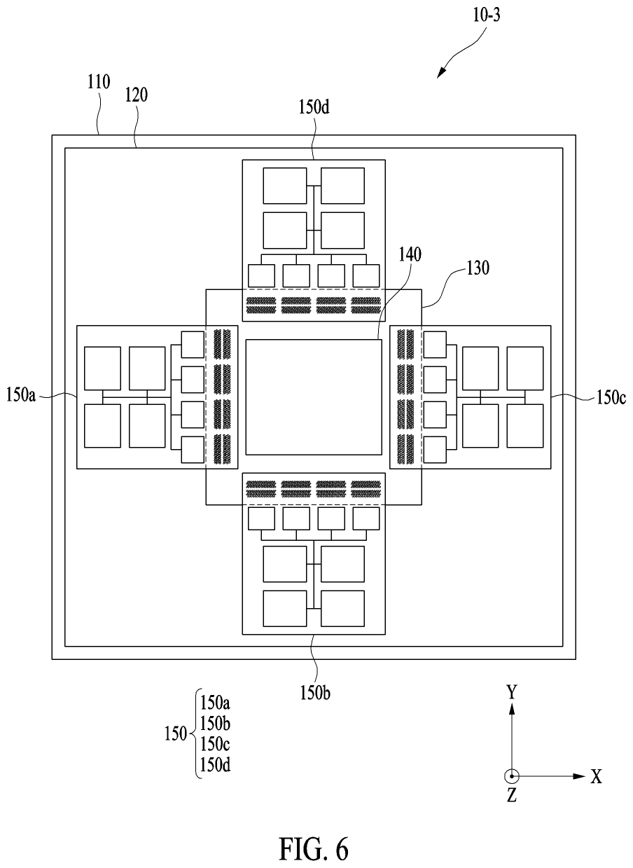

FIG. 5 is a schematic plan view of a semiconductor device according to an embodiment. FIG. 6 is a schematic plan view of a semiconductor device according to an embodiment.

Referring to FIGS. 5 and 6, in a semiconductor device 10-2 or 10-3 according to an embodiment, the processor die 150 may be provided in plural. The plurality of processor dies 150 may each be electrically connected to a single logic die 130. The plurality of processor dies 150 may be arranged on the redistribution substrate 120 so that at least partial areas thereof may each vertically overlap with the single logic die 130. For example, the plurality of processor dies 150 may be arranged along at least a portion of the outer perimeter of the single logic die 130. Each of the plurality of processor dies 150 may be electrically connected to the logic die 130 in the manner as described above with reference to FIG. 2 or FIG. 4, through the area vertically overlapping with the logic die 130. The plurality of processor dies 150 may transmit and receive data to and from the memory stack 140 through the single logic die 130. Further, the plurality of processor dies 150 may transmit and receive data to and from each other through the single logic die 130. For example, as shown in FIG. 5, two processor dies 150a and 150b may be arranged on both sides (e.g., the −X-directional and +X-directional sides) of the single logic die 130, respectively. For example, as shown in FIG. 6, four processor dies 150a, 150b, 150c, and 150d may be arranged on the up, down, left, and right sides (e.g., the +Y-directional, −Y-directional, −X-directional, and +X-directional sides) of the single logic die 130, respectively. However, these are merely examples, and the number and positions of processor dies 150 are not limited thereto. Meanwhile, in an embodiment, in a manner substantially similar to FIGS. 5 and 6, a plurality of logic dies may each be electrically connected to a single processor die.

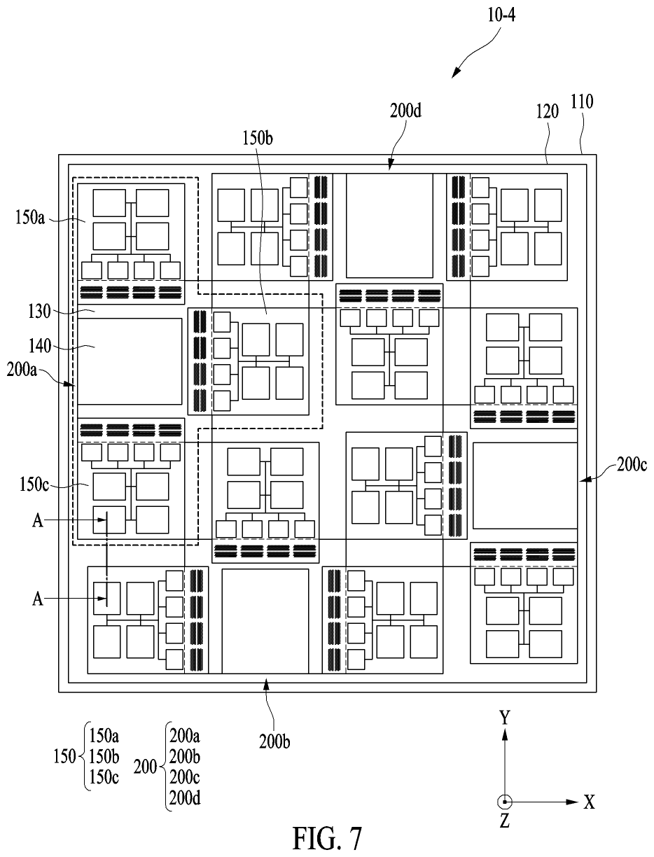

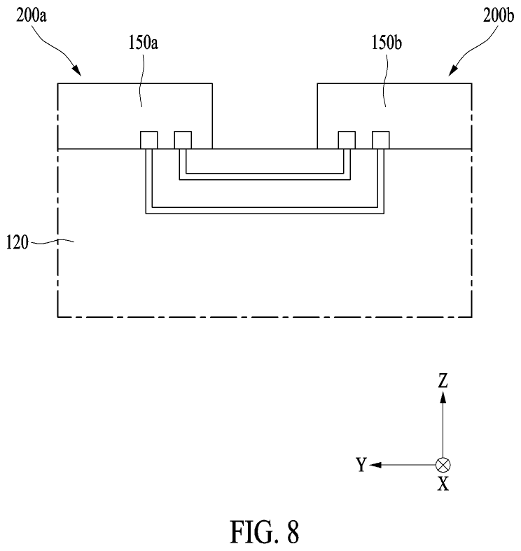

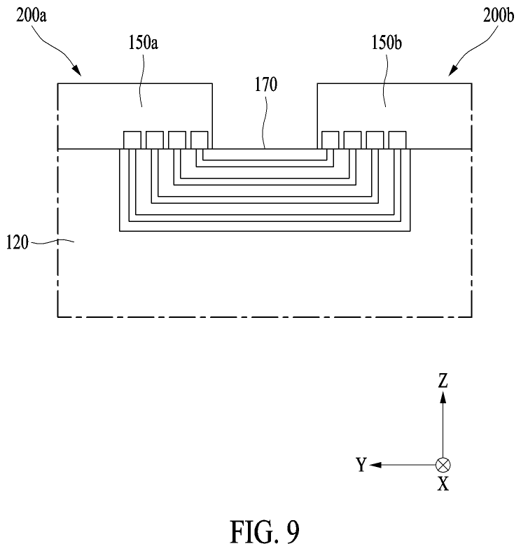

FIG. 7 is a schematic plan view of a semiconductor device according to an embodiment. FIG. 8 is a partial cross-sectional view of the semiconductor device according to an embodiment, the partial cross-sectional view taken along a line A-A of FIG. 7. FIG. 9 is a partial cross-sectional view of the semiconductor device according to an embodiment, the partial cross-sectional view taken along the line A-A of FIG. 7.

Referring to FIG. 7, in a semiconductor device 10-4 according to an embodiment, the logic die 130, the memory stack 140, and the processor die 150 may each be provided in plural. A single logic die 130, a single memory stack 140 stacked on the single logic die, and a plurality of processor dies 150 overlapping with the single logic die 130 may be called a single unit structure 200, the unit structure 200 may be provided in plural. The plurality of unit structures 200 may be arranged on a single redistribution substrate 120. For example, as shown in FIG. 7, a single unit structure 200 may include a single logic die 130, a single memory stack 140, and three processor dies 150a, 150c, and 150c, and four unit structures 200a, 200b, 200c, and 200d may be arranged on the single redistribution substrate 120. However, FIG. 7 merely shows an example, and the configuration and arrangement of unit structures 200 are not limited thereto. For example, a unit structure 200 may include one or more logic dies 130, one or more memory stacks 140 respectively stacked on the one or more logic dies 130, and one or more processor dies 150 respectively overlapping with the one or more logic dies 130.

Referring to FIGS. 7 and 8, in an embodiment, the plurality of unit structures 200 may be electrically connected to each other through the redistribution substrate 120. For ease of description, if the plurality of unit structures 200 includes a first unit structure 200a and a second unit structure 200b, a processor die 150a of the first unit structure 200a and a processor die 150b of the second unit structure 200b may be electrically connected to each other through wiring of the redistribution substrate 120 as shown in FIG. 8. In other words, the processor die 150a of the first unit structure 200a and the processor die 150b of the second unit structure 200b may transmit and receive data to and from each other through the wiring of the redistribution substrate 120.

Referring to FIGS. 7 and 9, in an embodiment, a semiconductor device 10-4 may further include a bridge substrate 170. The plurality of unit structures 200 may be electrically connected to each other through the bridge substrate 170 separately embedded in the redistribution substrate 120. As an example, if the plurality of unit structures 200 includes the first unit structure 200a and the second unit structure 200b, the bridge substrate 170 may be embedded in the redistribution substrate 120 between the processor die 150a of the first unit structure 200a and the processor die 150b of the second unit structure 200b, as shown in FIG. 9. For example, the bridge substrate 170 may be embedded in the redistribution substrate 120 so that at least a portion thereof may be exposed from the top surface of the redistribution substrate 120. For example, the top surface of the bridge substrate 170 and the top surface of the redistribution substrate 120 may be positioned substantially on a same plane (e.g., coplanar). High-density wiring may be formed in the bridge substrate 170. For example, the bridge substrate 170 may be formed of a passive bridge not including a separate active circuit. For example, the bridge substrate 170 may be formed of a silicon substrate. One area of the bridge substrate 170 may vertically overlap with the processor die 150a of the first unit structure 200a, and the other area of the bridge substrate 170 may vertically overlap with the processor die 150b of the second unit structure 200b. The one area of the bridge substrate 170 and the other area of the bridge substrate 170 may be electrically connected to the processor die 150a of the first unit structure 200a and the processor die 150b of the second unit structure 200b through bonding portions, respectively. By the structure described above, the processor die 150a of the first unit structure 200a and the processor die 150b of the second unit structure 200b may be electrically connected to each other through the bridge substrate 170 interposed therebetween. In other words, the processor die 150a of the first unit structure 200a and the processor die 150b of the second unit structure 200b may transmit and receive data to and from each other at high bandwidth through the high-density wiring of the bridge substrate 170 interposed therebetween.

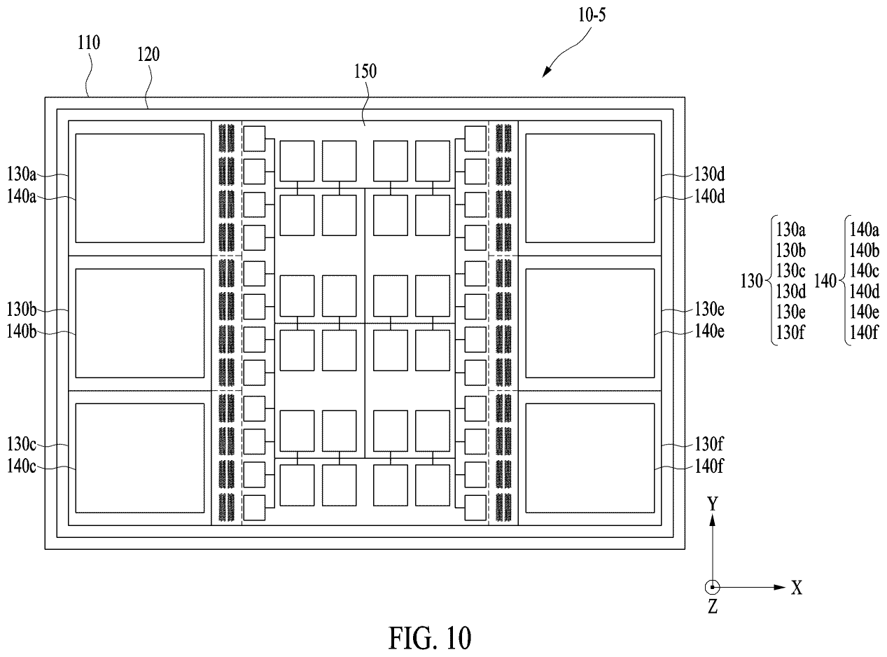

FIG. 10 is a schematic plan view of a semiconductor device according to an embodiment.

Referring to FIG. 10, in a semiconductor device 10-5 according to an embodiment, the logic die 130 may be provided in plural. The memory stack 140 may be provided in a number corresponding to the number of logic dies 130, and may be stacked on the logic dies 130, respectively. The plurality of logic dies 130 may be arranged in and/or on a single redistribution substrate 120 so that at least partial areas thereof may each vertically overlap with a single processor die 150. For example, the plurality of logic dies 130 may be arranged along at least a portion of the outer perimeter of the single processor die 150. Each of the plurality of logic dies 130 may be electrically connected to the single processor die 150 in the manner discussed above with respect to FIG. 2 or FIG. 4, through the area vertically overlapping with the single processor die 150. In this case, processor cores, the number of which corresponds to the number of memory stacks 140, may be formed in the single processor die 150 to control the plurality of memory stacks 140, respectively. For example, the single processor die 150 may be formed with a length corresponding to the total length of the edges of the plurality of logic dies 130 to be connected, or in a greater length, so that the plurality of logic dies 130 may be connected to one side (e.g., edge) thereof. For example, as shown in FIG. 10, the processor die 150 may be formed with a length (e.g., the Y-directional length) corresponding to three logic dies 130. For example, three logic dies 130a, 130b, and 130c may be positioned to overlap with one side (e.g., the −X-directional edge) of the single processor die 150, and the other three logic dies 130d, 130e, and 130f may be positioned to overlap with the other side (e.g., the +X-directional edge) of the single processor die 150. By the structure described above, six memory stacks 140a, 140b, 140c, 140d, 140e, and 140f may be electrically connected to the single processor die 150. However, this is merely an example, and the numbers, sizes, and arrangements of logic dies 130, memory stacks 140, and processor dies 150 are not limited thereto. The logic die 130, the memory stack 140, and the processor die 150 may be configured in various numbers, sizes, and arrangements.

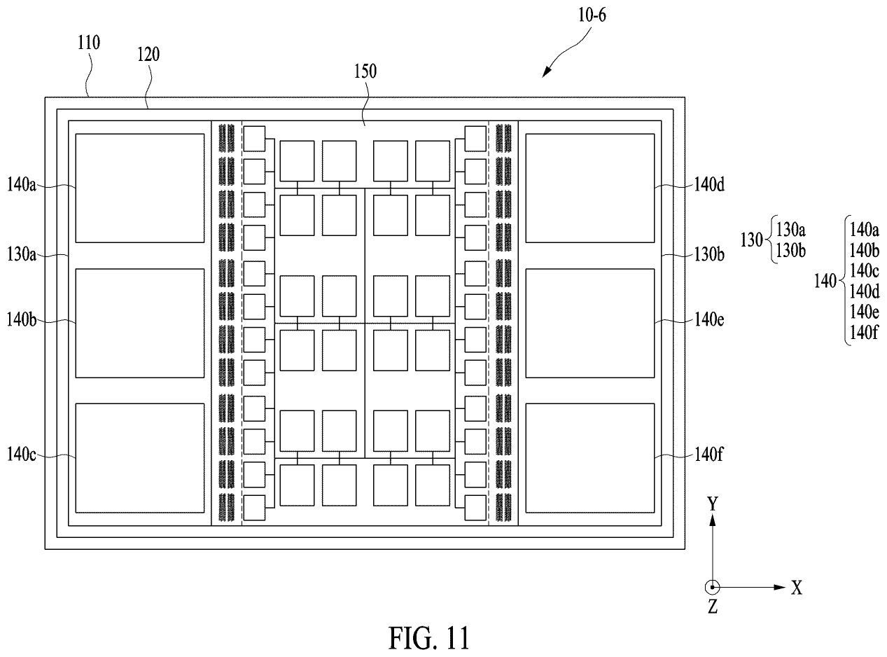

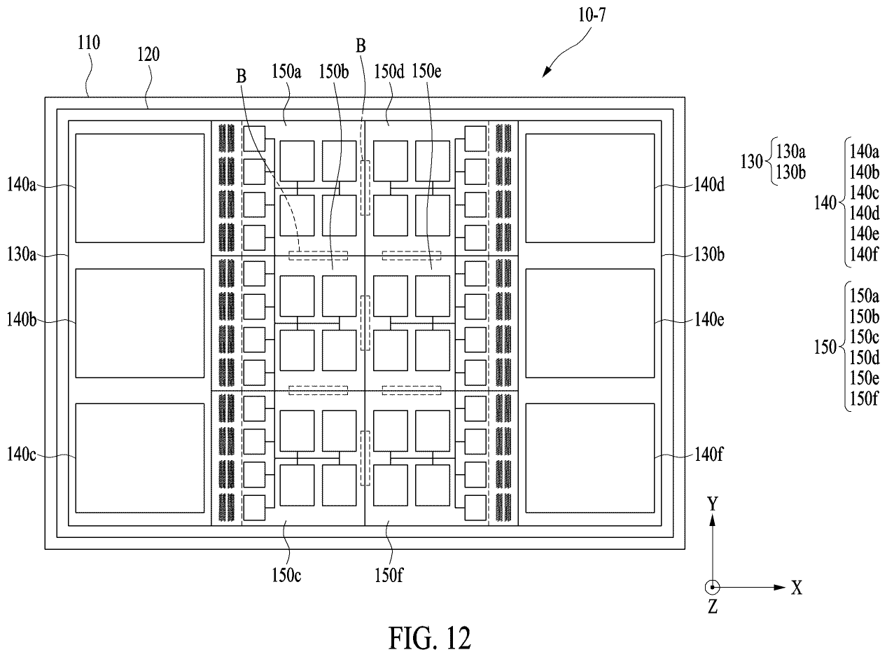

FIG. 11 is a schematic plan view of a semiconductor device according to an embodiment. FIG. 12 is a schematic plan view of a semiconductor device according to an embodiment.

Referring to FIGS. 11 and 12, in a semiconductor device 10-6 or 10-7 according to an embodiment, the memory stack 140 may be provided in plural, and the plurality of memory stacks 140 may be arranged on a single logic die 130a or 130b. For example, the single logic die 130a or 130b may be formed with an area larger than the total area of the plurality of memory stacks 140, so that the plurality of memory stacks 140 may be stacked thereon. For example, as shown in FIG. 11, three memory stacks 140a, 140b, and 140c or 140d, 140e, and 140f may be stacked on the single logic die 130a or 130b. However, this is merely an example, and the numbers, sizes, and arrangements of memory stacks 140 and logic dies 130 are not limited thereto. The memory stack 140 and the logic die 130 may be configured in various numbers, sizes, and arrangements.

Referring to FIG. 11, the single logic die 130a or 130b may be arranged in and/or on the single redistribution substrate 120 so that at least a partial area thereof may overlap with the single processor die 150. The single logic die 130a or 130b may be electrically connected to the single processor die 150 in the manner described above with respect to FIG. 2 or FIG. 4, through the area vertically overlapping with the single processor die 150. In this case, processor cores, the number of which corresponding to the number of memory stacks 140, may be formed in the single processor die 150 to control the plurality of memory stacks 140, respectively. By the structure described above, each of the plurality of memory stacks 140a, 140b, 140c; 140d, 140e, and 140f may be electrically connected to the single processor die 150 through a corresponding single logic die 130a or 130b.

Referring to FIG. 12, the single logic die 130a or 130b may be arranged in and/or on the single redistribution substrate 120 so that at least a partial area thereof may overlap with the plurality of processor dies 150. The single logic die 130a or 130b may be electrically connected to each of the processor dies 150a, 150b, and 150c or 150d, 150e, and 150f in the manner described above with respect to FIG. 2 or FIG. 4, through the area vertically overlapping with each of the processor dies 150a, 150b, and 150c or 150d, 150e, and 150f. By the structure described above, each of the plurality of memory stacks 140a, 140b, 140c, 140d, 140e, and 140f may be electrically connected to a corresponding single processor die 150a, 150b, 150c, 150d, 150e, or 150f through a corresponding single logic die 130a or 130b.

Referring to FIG. 12, two processor dies 150 positioned close to each other may be electrically connected to each other through the redistribution substrate 120. For example, the two processor dies 150 positioned close to each other may be electrically connected to each other through wiring formed in the redistribution substrate 120 in an area B, in the manner described above with respect to FIG. 8. By the structure described above, the plurality of processor dies 150 may transmit and receive data to and from each other through the wiring formed in the redistribution substrate 120. Meanwhile, this is merely an example, and the two processor dies 150 positioned close to each other may be electrically connected to each other through a bridge substrate (e.g., the bridge substrate 170 of FIG. 9) separately embedded in the redistribution substrate 120 in the area B, in the manner described above with respect to FIG. 9.

However, this is merely an example, and the numbers, sizes, and arrangements of logic dies 130, memory stacks 140, and processor dies 150 are not limited thereto. The logic die 130, the memory stack 140, and the processor die 150 may be configured in various numbers, sizes, and arrangements.

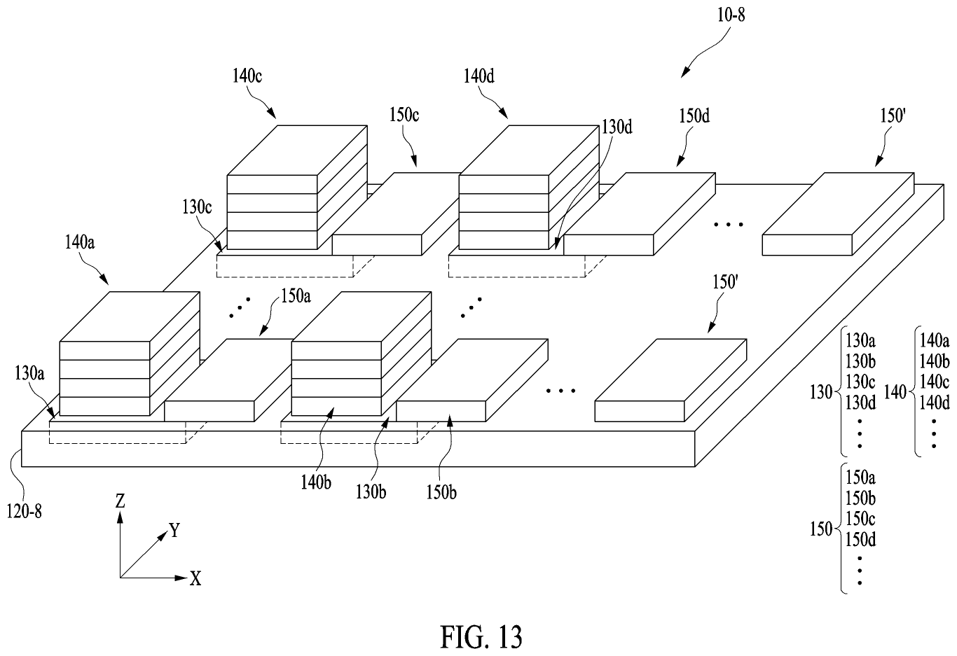

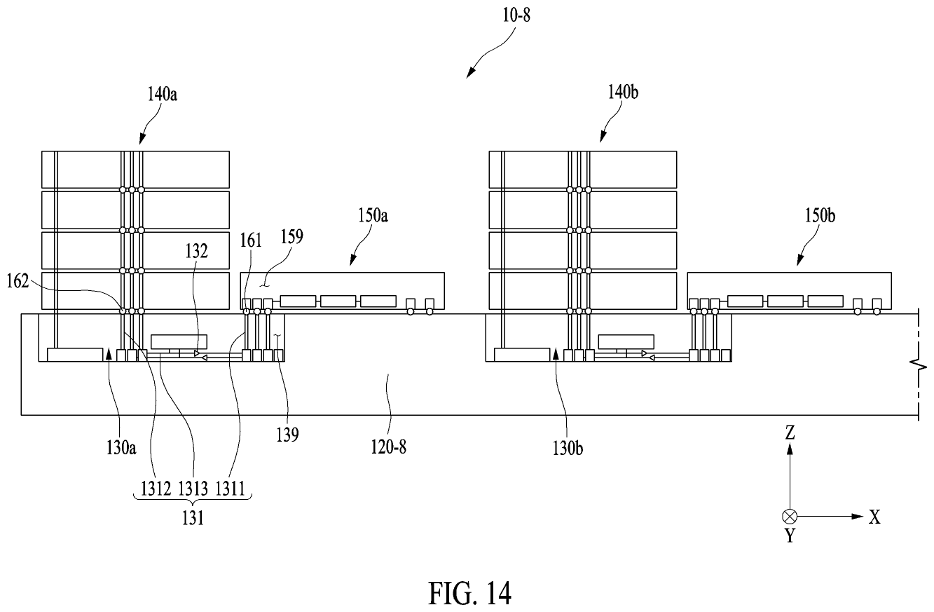

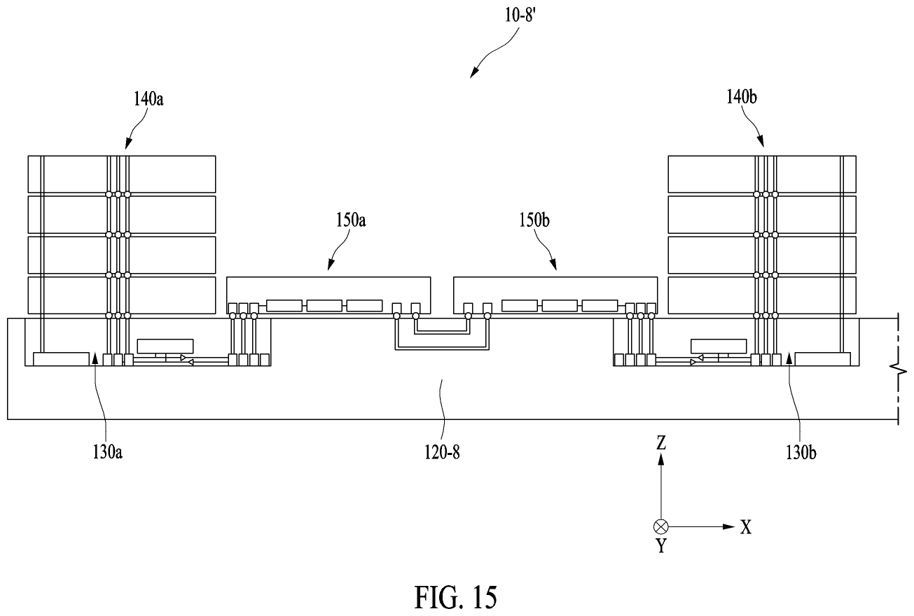

FIG. 13 is a schematic perspective view of a semiconductor device according to an embodiment. FIG. 14 is a schematic partial cross-sectional view of the semiconductor device according to an embodiment. FIG. 15 is a schematic partial cross-sectional view of a semiconductor device according to an embodiment. In describing a semiconductor device 10-8 or 10-8′ of FIGS. 13 to 15, the description of the semiconductor device 10 provided with reference to FIGS. 1 to 3 may apply thereto, unless otherwise described.

Referring to FIGS. 13 to 15, according to an embodiment, the semiconductor device 10-8 or 10-8′ may be a semiconductor device having a wafer scale. The semiconductor device 10-8 or 10-8′ may include a redistribution substrate 120-8, a plurality of logic dies 130, a plurality of memory stacks 140, and a plurality of processor dies 150.

In an embodiment, the redistribution substrate 120-8 may have a wafer scale. For example, the redistribution substrate 120-8 may be formed in one piece on a single wafer. The redistribution substrate 120-8 may include a redistribution path for electrically connecting the component (e.g., the logic die 130, the memory stack 140, and/or the processor die 150) disposed in and/or the upper portion of the redistribution substrate 120-8 and the component disposed in and/or on the lower portion of the redistribution substrate 120 to each other.

In an embodiment, each of the plurality of logic dies 130 may be embedded in the redistribution substrate 120-8 so that at least a portion thereof may be exposed from the top surface of the redistribution substrate 120-8. Each of the plurality of logic dies 130 may include a first connection area 139. The plurality of memory stacks 140 may be stacked on the logic dies 130, respectively. Each of the plurality of processor dies 150 may be stacked on the redistribution substrate 120-8 so that at least a portion thereof may vertically overlap with a corresponding logic die 130. Each of the plurality of processor dies 150 may include a second connection area 159 vertically overlapping with the first connection area 139 of a corresponding logic die 130. The logic die 130 and the processor die 150 corresponding to each other may be directly connected to each other through the first bonding portion 161 on each of the first connection area 139 and the second connection area 159. Each memory stack 140 may transmit and receive data to and from a corresponding processor die 150 via a pathway including a corresponding logic die 130, not including the redistribution substrate 120-8.

In an embodiment, each of the plurality of logic dies 130 may include a signal path 131 for transmitting and receiving data between a corresponding memory stack 140 and a corresponding processor die 150, and a signal driver 132 for adjusting a signal transmitted along the signal path 131. For example, the signal path 131 may include a first through-silicon via 1311 electrically connected to a corresponding processor die 150 through the first bonding portion 161 and positioned in the first connection area 139, a second through-silicon via 1312 electrically connected to a corresponding memory stack 140 through the second bonding portion 162, and connection wiring 1313 electrically connecting the first through-silicon via 1311 and the second through-silicon via 1312 to each other. Alternatively, in an embodiment, a signal path (e.g., the signal path 131-1 of FIG. 4) may include connection wiring (e.g., the connection wiring 1313-1 of FIG. 4) formed in the upper portion of each logic die (e.g., the logic die 130-1 of FIG. 4), wherein one side of the connection wiring (e.g., the connection wire 1313-1 of FIG. 4) may be electrically connected to a corresponding processor die 150 through the first bonding portion 161, and the other side of the connection wiring (e.g., the connection wire 1313-1 of FIG. 4) may be electrically connected to a corresponding memory stack 140 through the second bonding portion 162.

In an embodiment, among the plurality of processor dies 150, a processor die 150′ may perform a separate task without being directly connected to any of the memory stacks 140. In this case, the processor die 150′ may communicate with another processor die 150 and a memory stack 140 through a communication module. In an embodiment, the semiconductor device 10-8 or 10-8′ may further include an artificial intelligence (AI) accelerator.

In an embodiment, two processor dies (e.g., the processor dies 150a and 150b) positioned close to each other may be electrically connected to each other through the redistribution substrate 120-8. For example, as shown in FIG. 15, the two processor dies (e.g., the processor dies 150a and 150b) positioned close to each other may be electrically connected to each other through the wiring formed in the redistribution substrate 120-8 in the manner described above with respect to FIG. 8. By the structure described above, the two processor dies (e.g., the processor dies 150a and 150b) positioned close to each other may transmit and receive data to and from each other through the wiring formed in the redistribution substrate 120-8. Meanwhile, this is merely an example, and the two processor dies (e.g., the processor dies 150a and 150b) positioned close to each other may be electrically connected to each other through a bridge substrate (e.g., the bridge substrate 170 of FIG. 9) separately embedded in the redistribution substrate 120-8 in the manner described above with respect to FIG. 9.

However, FIGS. 13 to 15 are merely examples, and the numbers and arrangements of logic dies 130, memory stacks 140, and processor dies 150 are not limited thereto. Further, the embodiments described with reference to FIGS. 1 to 15 may be combined within the scope in which they do not conflict with each other.

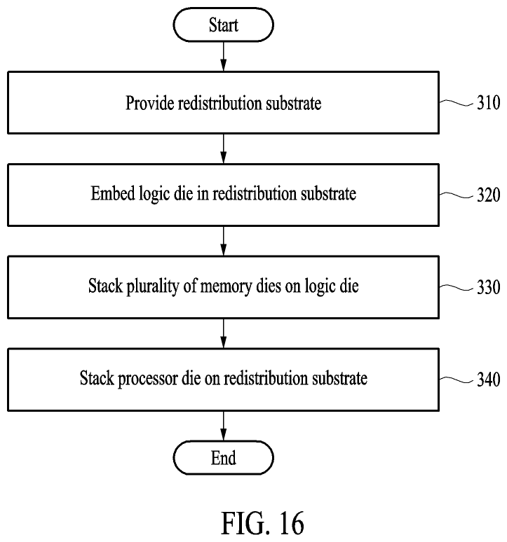

FIG. 16 is a flowchart illustrating a method of manufacturing a semiconductor device according to an embodiment.

The method of manufacturing a semiconductor device of FIG. 16 may be a method of manufacturing the semiconductor device described with reference to FIGS. 1 to 15. In describing the method of manufacturing a semiconductor device, a detailed description of the content described above may not be repeated, and the above description may apply thereto.

The method of manufacturing a semiconductor device may include an operation 310 of providing a redistribution substrate, an operation 320 of embedding a logic die in the redistribution substrate, an operation 330 of stacking a memory stack on the logic die, and an operation 340 of stacking a processor die on the redistribution substrate.

In the operation 310, a redistribution substrate may be provided. The redistribution substrate may be a substrate on which a logic die, a memory stack, and/or a processor die are to be disposed. For example, the redistribution substrate may be formed of an organic substrate. For example, the redistribution substrate may be stacked on a package substrate.

In the operation 320, a logic die may be embedded in the redistribution substrate so that at least a portion of the logic die may be exposed from the top surface of the redistribution substrate. The logic die may include an active circuit (e.g., a signal amplifying element or a buffering element). The logic die may include a signal path for transmitting and receiving data between a corresponding memory stack and a corresponding processor die.

The operation 320 may include a trench process, a laminating process, and/or a molding process. For example, the operation 320 may include an operation of forming a cavity in the top surface of the redistribution substrate (e.g., the trench process), an operation of positioning the logic die in the cavity, and an operation of laminating around the logic die. In the laminating operation, while causing at least a portion of the logic die to be exposed from the top surface of the redistribution substrate, the remaining portion of the logic die in the cavity may be laminated. As another example, a method of planting vias (e.g., Cu-vias) in a temporary carrier and placing and then molding the logic die therebetween may also be used. However, this is merely an example, and the process of embedding the logic die in the redistribution substrate is not limited thereto.

In the operation 330, a plurality of memory dies may be stacked on the logic die. The plurality of memory dies may include memory dies that are vertically stacked.

Meanwhile, although an example of embedding the logic die in the redistribution substrate and then stacking the plurality of memory dies thereon has been described with respect to operations 320 and 330, it is also possible to embed the logic die in the redistribution substrate after stacking a plurality of memory dies on the logic die in advance. For example, a memory device may be separately manufactured in a form where a plurality of memory dies are stacked sequentially on the logic die. The separately manufactured memory device may be embedded in the redistribution substrate. For example, the memory device may be placed within the redistribution substrate to the height of the logic die. However, this is merely an example, and the order and method of operations 320 and 330 are not limited thereto.

In the operation 340, a processor die may be stacked on the redistribution substrate so that a partial area of the processor die may overlap with the logic die. The logic die and the processor die may be connected to each other through a bonding portion in the overlapping area. For example, the logic die and the processor die may be connected through the bonding portion in the overlapping area so that the wiring of the logic die and the wiring of the processor die may be at least partially vertically aligned. For example, the logic die and the processor die may be connected to each other through a micro bump or hybrid copper bonding structure. By the structure described above, the memory stack may transmit and receive data to and from the processor die via a pathway including the logic die, not including the redistribution substrate.

Meanwhile, FIG. 16 is merely an example, and the order of operations is not limited thereto. For example, the operations may be performed in a different order unless they contradict each other. Also, any other operations may be added between the operations.

Non-limiting example embodiments have been described above with reference to the drawings. Nevertheless, it should be understood that various modifications and variations may be made to these example embodiments. For example, suitable results may be achieved if the described techniques are performed in a different order, and/or if components in a described system, architecture, device, or circuit are combined in a different manner, and/or replaced or supplemented by other components or their equivalents. Accordingly, such modifications and variations are within the scope of the present disclosure.

What is claimed is:

1. A semiconductor device comprising:
a package substrate;
a redistribution substrate on the package substrate in a first direction;
a logic die embedded in the redistribution substrate so that at least a portion of the logic die is exposed from a surface of the redistribution substrate, the surface facing in the first direction, and the logic die comprising an active circuit and a first connection area;
a memory stack comprising a plurality of memory dies stacked on the logic die in the first direction; and
a processor die on the redistribution substrate in the first direction, the processor die comprising a second connection area overlapping with the first connection area in the first direction,
wherein wiring of the logic die and wiring of the processor die are electrically connected through a first bonding portion on the first connection area and the second connection area so that wiring of the logic die and wiring of the processor die are at least partially aligned in the first direction.

2. The semiconductor device of claim 1, wherein the first bonding portion comprises a micro bump or hybrid copper bonding structure.

3. The semiconductor device of claim 1, wherein the memory stack is configured to transmit and receive data to and from the processor die via a pathway including the logic die and not including the redistribution substrate.

4. The semiconductor device of claim 1, wherein the logic die comprises:
a signal path for transmitting and receiving data between the memory stack and the processor die; and
a signal driver configured to adjust a signal transmitted along the signal path.

5. The semiconductor device of claim 4, wherein the signal path comprises:
a first through-silicon via in the first connection area, the first through-silicon via electrically connected to the processor die through the first bonding portion;
a second through-silicon via electrically connected to the memory stack through a second bonding portion; and
connection wiring electrically connecting the first through-silicon via and the second through-silicon via.

6. The semiconductor device of claim 4, wherein the signal path comprises connection wiring in an upper portion of the logic die, and
wherein one side of the connection wiring is electrically connected to the processor die through the first bonding portion, and another side of the connection wiring is electrically connected to the memory stack through a second bonding portion.

7. The semiconductor device of claim 1, wherein the logic die comprises at least one from among an integrated voltage regulator (IVR), a memory controller (MC), a switch circuit, a network-on-chip (NoC), a static random-access memory (SRAM), a digital signal processor (DSP), and a neural processing unit (NPU).

8. The semiconductor device of claim 4, wherein the logic die and the processor die are configured to transmit and receive data at a first bandwidth through the signal path of the logic die, and transmit and receive data at a second bandwidth through wiring of the redistribution substrate, and
wherein the first bandwidth is higher than the second bandwidth.

9. The semiconductor device of claim 1, wherein the redistribution substrate comprises an organic substrate, and
wherein the logic die comprises a silicon substrate, a gallium nitride (GaN) substrate, or a glass substrate.

10. The semiconductor device of claim 1, further comprising an additional processor die on the redistribution substrate in the first direction,
wherein the processor die and the additional processor die overlap with the logic die in the first direction, and are electrically connected to the logic die.

11. The semiconductor device of claim 10, further comprising a unit structure comprising the logic die, the memory stack, the processor die, and the additional processor die,
wherein the semiconductor device comprises a plurality of the unit structure on the redistribution substrate.

12. The semiconductor device of claim 11, wherein the processor die of a first unit structure, from among the plurality of the unit structure, and the processor die of a second unit structure, from among the plurality of the unit structure, are electrically connected through wiring of the redistribution substrate.

13. A semiconductor device comprising:
a redistribution substrate;
a memory stack comprising:
a base die embedded in the redistribution substrate so that at least a portion of the base die is exposed from a surface of the redistribution substrate, the surface facing in a first direction; and
a memory die on the base die in the first direction; and
a processor die on the redistribution substrate in the first direction, the processor die comprising an area overlapping with the base die in the first direction,
wherein the base die and the processor die are connected to each other through a bonding portion on the area, and
wherein the base die comprises a signal amplifying element or a buffering element.

14. The semiconductor device of claim 13, wherein the memory die is configured to transmit and receive data to and from the processor die via a pathway including the base die and not including the redistribution substrate.

15. The semiconductor device of claim 13, wherein the base die comprises a signal path for transmitting and receiving data between the memory die and the processor die.

16. The semiconductor device of claim 15, wherein the signal path comprises:
a first through-silicon via electrically connected to the processor die;
a second through-silicon via electrically connected to the memory die; and
connection wiring electrically connecting the first through-silicon via and the second through-silicon via.

17. The semiconductor device of claim 15, wherein the base die and the processor die are bonded through a micro bump or hybrid copper bonding structure on the area.

18. A method of manufacturing a semiconductor device, the method comprising:
embedding a logic die in a redistribution substrate such that at least a portion of the logic die is exposed from a surface of the redistribution substrate, the surface facing in a first direction, and the logic die including an active circuit;
stacking a plurality of memory dies on the logic die in the first direction; and
stacking a processor die on the redistribution substrate in the first direction such that an area of the processor die overlaps with the logic die in the first direction,
wherein the stacking the processor die comprises connecting the logic die and the processor die through a bonding portion on the area.

19. The method of claim 18, wherein the bonding portion includes a micro bump or a hybrid copper bonding structure.

20. The method of claim 18, wherein the embedding the logic die in the redistribution substrate comprises:
forming a cavity in the surface of the redistribution substrate;
placing the logic die in the cavity; and
laminating around the logic die.
